(19) United States
(12) Patent Application Publication
(10) Pub. No.: US 2026/0106636 A1
(43) Pub. Date: Apr. 16, 2026

(54) RADIO FREQUENCY TRANSISTOR AMPLIFIERS HAVING DISTRIBUTED PRE-DISTORTION NETWORKS FOR IMPROVED LINEARIZATION

(71) Applicant: MACOM Technology Solutions Holdings, Inc., Lowell, MA (US)

(72) Inventor: Kohei Fujii, San Jose, CA (US)

(21) Appl. No.: 18/915,462

(22) Filed: Oct. 15, 2024

(51) Int. Cl. H04B 1/04; H03F 1/32; H03F 1/56; H03F 3/19

(52) U.S. Cl. CPC H04B 1/0475; H03F 1/3241; H03F 1/56; H03F 3/19; H03F 2200/222; H03F 2200/451; H04B 2001/0425

(57) ABSTRACT

An RF transistor amplifier system comprises an RF transistor amplifier and a pre-distortion circuit that comprises a plurality of transistors coupled between a conductive path and a reference voltage.

### FIELD

The present invention relates to radio frequency transistor amplifiers and, more particularly, to RF transistor amplifiers having pre-distortion networks.

### BACKGROUND

Radio frequency transistor amplifiers having high power handling capability are used in a wide variety of applications including, for example, cellular communications, satellite communications, radar systems and various military applications. To provide increased output power, these radio frequency transistor amplifiers may include transistors having large effective gate peripheries. One technique for increasing the effective gate periphery of a transistor is to provide a plurality of unit cell transistors that are connected in parallel. In such a device, the effective gate periphery may be the sum of the gate peripheries of the individual unit cell transistors. Note that herein the term “radio frequency” (abbreviated as “RF”) is used broadly to refer to signals having frequencies in the range of 300 MHz to 300 GHz.

Field effect transistors are widely used to implement RF transistor amplifiers. For RF transistor amplifiers that operate at high frequencies and/or high output power levels, the field effect transistors are often implemented using wide bandgap semiconductor materials, which are semiconductor materials that have a band-gap of at least 1.4 eV. Wide band-gap semiconductor materials have a number of advantageous characteristics as compared to lower bandgap semiconductor materials (e.g., silicon) including high electric field strength, which results in better RF power handling capabilities, improved power switching, and lower switching losses. In addition, the larger band-gap results in a lower number of intrinsic carriers within the semiconductor material, which means that wide band-gap semiconductor devices can operate at higher temperatures before thermally-activated carriers cause unintentional conductivity in various layers of the device (e.g., in a buffer layer). Wide band-gap semiconductor devices also tend to be more robust than lower band-gap semiconductor devices, with the ability to handle higher temperatures and the like.

One widely used class of wide bandgap semiconductor materials are “Group III nitride” semiconductor materials. As used herein, the term “Group III nitride” refers to compound semiconductor materials formed between nitrogen and one or more elements in Group III of the periodic table, usually aluminum (“AI”), gallium (“Ga”), indium (“In”) and/or scandium (“Sc”). The term “Group III nitride” therefore encompasses compound semiconductor material formed of a single Group III element and nitrogen such as, for example, gallium nitride (“GaN”), aluminum nitride (“AlN”) and indium nitride (“InN”), and also encompasses materials that include two or more Group III elements such as aluminum gallium nitride (“AlGaN”), aluminum indium gallium nitride (“AlInGaN”) and the like. Group III nitride semiconductor materials have empirical formulas in which one mole of nitrogen is combined with a total of one mole of the Group III elements.

Group III nitride RF transistor amplifiers are typically implemented as High Electron Mobility Transistors (“HEMT”). Group III nitride HEMTs are well suited for operation as RF transistor amplifiers as the high electric field strength of the Group III nitride semiconductor materials allows large voltages to be applied to these devices. Moreover, lateral versions of these devices have relatively high electron mobility, and the heterostructures formed in these devices can have extremely high polarization charge so that the two dimensional electron gas (2DEG) that forms at the heterojunction has both a large number of carriers and relatively high carrier mobility.

The RF transmission lines that are commonly used to connect an RF transistor amplifier to other components of an RF communications system often have impedances that may differ significantly from the impedances at the inputs and/or outputs of commercially available RF transistor amplifiers. Consequently, input and/or output impedance matching networks are typically provided to maintain low return loss values. In some cases, these impedance matching networks are implemented separately from the RF transistor amplifier, and may be external to the RF transistor amplifier package or incorporated into the package. In other cases, one or more RF transistor amplifiers along with their associated feed networks and impedance matching circuits are all implemented on the semiconductor die as a single integrated circuit. Such devices are referred to as monolithic microwave integrated circuit (“MMIC”) devices.

One challenge with the use of RF transistor amplifiers is that they exhibit non-linear behavior. A truly linear RF transistor amplifier would generate output signals that have higher power levels, but otherwise are exact replicas of the input RF signal. Most RF transistor amplifiers exhibit relatively linear behavior at lower input power levels, but exhibit increasing non-linear behavior after the power of the input signal is increased beyond a certain level. Unfortunately, when two or more RF signals are passed through a non-linearity (e.g., an RF transistor amplifier operating in its non-linear region), the RF signals mix to generate additional RF signals at mathematical combinations of the original RF signals. These generated signals are called intermodulation products. Intermodulation products are undesirable because they deteriorate the quality of the RF signals transmitted by an RF communication system and because the RF signals that are generated at other frequencies may appear as interference to RF signals that are received by the RF communication system. In each case, the effect of the intermodulation products may be to increase the bit error rate of the RF signals, which may require a reduction in the data rate of the RF signals.

One technique that can be used to improve the linearity of an RF transistor amplifier is to use a predistortion circuit to “pre-distort” the RF signals that are input to the RF transistor amplifier. The pre-distortion system is designed to introduce amplitude and phase non-linearities into the RF signals that are input to the RF transistor amplifier prior to amplification. The introduced non-linearities may operate as “inverse distortion” that at least partially offsets the distortion resulting from the non-linear behavior of the RF transistor amplifier. These pre-distortion circuits may be designed to introduce little or no distortion at input power levels that correspond to the linear range of the RF transistor amplifier, and to generate increasing amounts of gain and phase distortion as the input power level is increased beyond the linear region of the RF transistor amplifier. The net effect is that a pre-distortion system can improve the linearity of an RF transistor amplifier system.

FIG. 1A is a circuit diagram of a conventional RF transistor amplifier system 1 that includes an RF signal source 10, a main amplifier circuit 20 and an analog predistortion circuit 30. The main amplifier circuit 20 may be any conventional amplifier circuit that includes one or more RF transistor amplifiers. The main amplifier circuit 20 may, for example, include a single RF transistor amplifier or may include two or more RF transistor amplifiers. If multiple RF transistor amplifiers are provided, they may be coupled in series (e.g., a multi-stage amplifier) and/or in parallel (e.g., a Doherty amplifier). When the main amplifier circuit 20 includes multiple amplifiers, a single pre-distortion circuit 30 is typically provided as shown in FIG. 1A that acts as a pre-distortion circuit for the multi-amplifier main amplifier circuit 20. However, it will be appreciated that pre-distortion circuits may alternatively be implemented for each amplifier of a multi-amplifier main amplifier circuit 20 in other cases.

As shown in FIG. 1A, the predistortion circuit 30 comprises a field effect transistor 40 that is coupled between the RF signal source 10 and the main amplifier circuit 20. The pre-distortion circuit 30 uses the non-linear characteristics of the drain-to-source resistance (“Ras”) of the field effect transistor 40 under zero direct current (“DC”) bias conditions to pre-distort the RF signals that are passed from the RF signal source 10 to the main amplifier circuit 20.

FIG. 1B is an equivalent circuit diagram of the RF transistor amplifier system 1 of FIG. 1A. As shown in FIG. 1B, the drain (“D”) of the field effect transistor 40 is coupled to the RF signal source and the source (“S”) of the field effect transistor 40 is coupled to the gate of the main RF transistor amplifier 20. The intrinsic drain-to-source capacitance (“C_{ds}”) of the field effect transistor 40 is coupled in parallel to the non-linear intrinsic drain-to-source resistance (“R_{ds}”) in between the drain and source of the field effect transistor 40. The field effect transistor 40 also has a non-linear intrinsic gate-to-drain capacitance (“C_{gd}”) and a non-linear intrinsic gate-to-source capacitance (“C_{gs}”). The gate (“G”) of the field effect transistor 40 is coupled to ground and to a DC bias voltage source. During operation, an appropriate DC bias voltage is applied to the gate terminal of field effect transistor 40 through the terminal labeled DC Bias in FIG. 1A. Appropriate bias voltages are also applied to the gate, drain and source terminals of the main RF transistor amplifier 20, and an RF driving signal is generated by the RF signal source 10 and applied to the source terminal of field effect transistor 40. The DC bias voltage that is applied to field effect transistor 40 may be set to be near the threshold voltage of field effect transistor 40 because the drain-to-source resistance R_{ds} non-linearity of field effect transistor 40 is most sensitive to changes in the RF driving signal at this gate voltage (see FIG. 2B, discussed below). The RF driving signal is superimposed over the gate-to-source DC bias voltage applied at the gate of field effect transistor 40. As a result, R_{ds} (V_{ds}+V_{RF}), C_{gs} (V_{gs}+V_{RF}) and C_{gd} (V_{gd}+V_{RF}) change as a function of the driving RF signal. If the RF driving signal is large enough to modulate the drain-to-source resistance R_{ds} (V_{ds}+V_{RF}), the insertion loss between the drain and source increases, because of the R_{ds} (V_{ds}+V_{RF}) voltage dependency. If the RF driving signal is large enough to modulate the gate-to-source capacitance C_{gs} (V_{gs}+V_{RF}) and the gate-to-drain capacitance C_{gd} (V_{gd}+V_{RF}), the insertion phase between the drain and source decreases, because of the C_{gs} (V_{gs}+V_{RF}) and C_{gd} (V_{gd}+V_{RF}) voltage dependency.

FIGS. 2A-2C are graphs illustrating the responses of the voltage dependent elements of the pre-distortion circuit 30 of FIG. 1A. As shown in FIGS. 2A and 2B, the intrinsic gate-to-drain capacitance C_{gd} of field effect transistor 40 increases with increasing gate-to-source bias voltage levels, while the intrinsic drain-to-source resistance (“R_{ds}”) of field effect transistor 40 decreases with increasing gate-to-source bias voltage levels, up to a gate-to-source voltage of about −1 volts. These two non-linear responses may generally offset each other so that they together provide a somewhat linear response at lower input power levels. As shown in FIG. 2C, the intrinsic gate-to-source capacitance C_{gs} of field effect transistor 40 remains relatively constant at gate-to-source voltage levels below about −1.5 volts. Thus, below gate-to-source voltage levels of about −1.5 volts, the pre-distortion circuit 30 will exhibit generally linear behavior.

As described above, the voltage-dependent non-linear response of the drain-to-source resistance R_{ds} (V_{ds}+V_{RF}) provides a non-linear response that may be used to pre-distort the gain of the RF signal input to the main transistor amplifier 20, and the voltage-dependent non-linear responses of the gate-to-source capacitance C_{gs} (V_{gs}+V_{RF}) and the gate-to-drain capacitance G_{gd} (V_{gd}+V_{RF}) provide non-linear responses that may be used to pre-distort the phase of the RF signal input to the main transistor amplifier 20.

### SUMMARY

Pursuant to some embodiments of the present invention, RF transistor amplifier systems are provided that comprise an RF transistor amplifier and a pre-distortion circuit that comprises a plurality of transistors, where each of the transistors is coupled between a conductive path and a reference voltage.

In some embodiments, the transistors may be part of an artificial transmission line that is coupled between an RF signal source and the RF transistor amplifier. In some embodiments, an impedance of the artificial transmission line may be set to match an impedance of the RF signal source

In some embodiments, each of the transistors may be a high electron mobility transistor, and wherein a drain of each of the transistors is coupled to the conductive path and a source of each of the transistors is coupled to the reference voltage. In some embodiments, a plurality of inductances may be provided along the conductive path, and the drain of each of the transistors is coupled to the conductive path between a respective pair of the inductances.

In some embodiments, gates of each of the transistors may be commonly coupled to a bias voltage source. In some embodiments, the pre-distortion circuit may further comprise a plurality of resistors, where each resistor is coupled between the bias voltage source and the gate of a respective one of the transistors.

In some embodiments, each of the transistors may be identical.

In some embodiments, drain-to-source resistances of the transistors may be used to pre-distort RF signals received from the RF signal source.

In some embodiments, a number of transistors included in the pre-distortion circuit may be selected to provide a pre-determined amount of pre-distortion.

Pursuant to further embodiments of the present invention, RF transistor amplifier systems are provided that comprise an RF signal source, an RF transistor amplifier, and an artificial transmission line coupled between the RF signal source and the RF transistor amplifier.

In some embodiments, the artificial transmission line may comprise a conductive path that connects the RF signal source to the RF transistor amplifier and a plurality of transistors that are coupled between the conductive path and a reference voltage. In some embodiments, an impedance of the artificial transmission line may be set to match an impedance of the RF signal source. In some embodiments, a drain of each of the plurality of transistors may be coupled to the conductive path and a source of each of the transistors may be coupled to the reference voltage. In some embodiments, a plurality of inductances may be provided along the conductive path, and the drain of each of the transistors may be coupled to the conductive path between a respective pair of the inductances. In some embodiments, gates of each of the plurality of transistors may be commonly coupled to a voltage source. In some embodiments, values of each of the inductances may be within 20% of each other. In some embodiments, the pre-distortion circuit may further comprise a plurality of resistors, where each resistor is coupled between the voltage source and the gate of a respective one of the transistors. In some embodiments, each of the transistors may be identical.

In some embodiments, the artificial transmission line may act as a pre-distortion circuit that is configured to improve a linearity of the RF transistor amplifier. In some embodiments, drain-to-source resistances of the transistors may be used to pre-distort RF signals received from the RF signal source.

In some embodiments, each of the transistors may be a high electron mobility transistor.

Pursuant to still further embodiments of the present invention, RF transistor amplifier systems are provided that comprise an RF signal source, an RF transistor amplifier, and an impedance matching network that comprises a plurality of inductances connected in series along a conductive path and a plurality of transistors that are shunt coupled to the conductive path. Values of the inductances and values of a drain-to-source capacitance of the field effect transistors are selected so that an impedance at an input of the impedance matching network matches an impedance of the RF signal source.

In some embodiments, the impedance matching network may further include a plurality of inductances that are provided along the conductive path. In some embodiments, a drain of each of the transistors may be coupled to the conductive path between a respective pair of the inductances, and a source of each transistor may be coupled to ground. In some embodiments, gates of each of the transistors may be commonly coupled to a bias voltage source.

In some embodiments, drain-to-source resistances of the transistors may be used to pre-distort RF signals received from the RF signal source. In some embodiments, a number of transistors included in the pre-distortion circuit may be selected to provide a pre-determined amount of pre-distortion.

### BRIEF DESCRIPTION OF THE FIGURES

FIG. 1A is a circuit diagram of a conventional RF transistor amplifier system that includes an analog pre-distortion circuit.

FIG. 1B is an equivalent circuit diagram of the RF transistor amplifier system of FIG. 1A.

FIGS. 2A-2C are graphs illustrating the responses of the voltage dependent elements of the pre-distortion circuit of FIG. 1A.

FIG. 3 is a circuit diagram of a conventional artificial transmission line that is coupled between a signal source and a load.

FIG. 4A is a circuit diagram of an RF transistor amplifier system according to certain embodiments of the present invention.

FIG. 4B is an equivalent circuit diagram of the RF transistor amplifier system of FIG. 4A.

### DETAILED DESCRIPTION

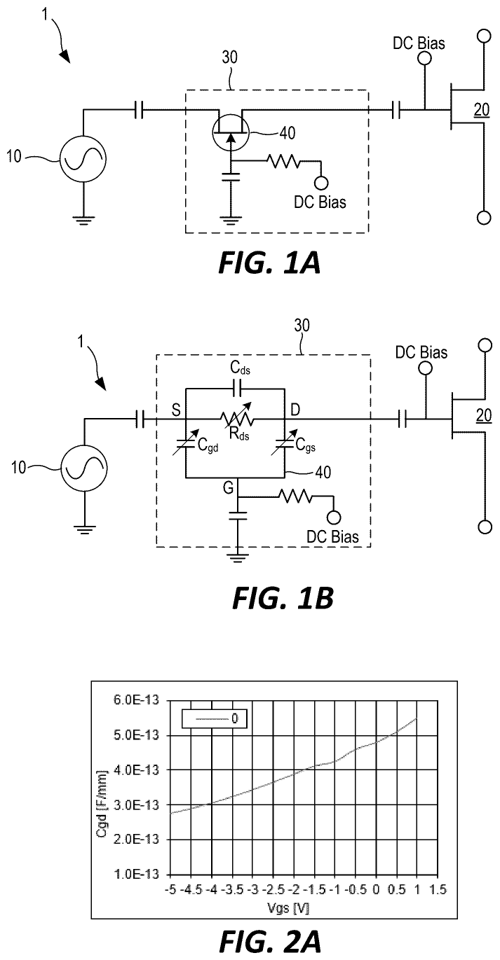

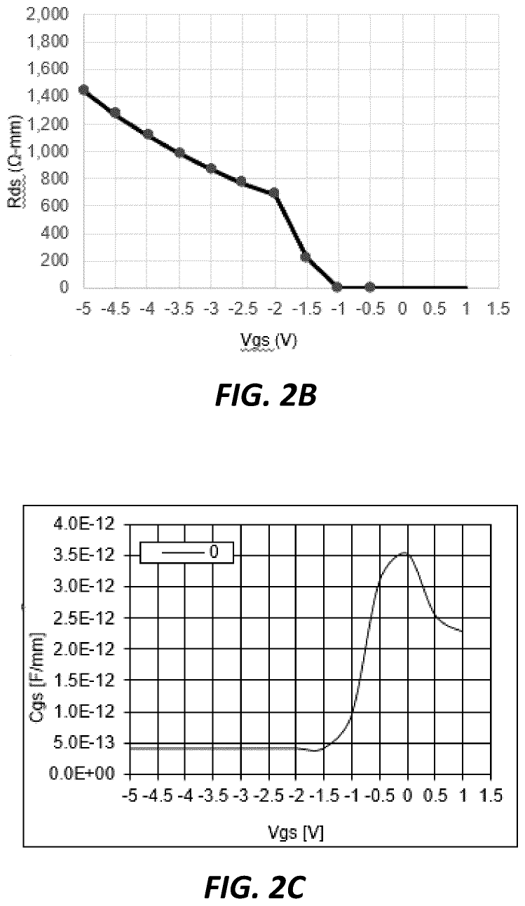

While the analog pre-distortion circuit 30 that is included in the conventional RF transistor amplifier system 1 of FIG. 1A may provide satisfactory performance in many applications, when the operating frequency of the main RF transistor amplifier is above about 30 GHz, impedance matching issues arise because of the intrinsic parasitic capacitances and inductances of field effect transistor 40. In particular, the pre-distortion circuit 30 should have a low insertion loss, since the insertion loss lowers the magnitude of the RF signals input to the main RF transistor amplifier 20. Generally, the size of a field effect transistor is the total gate width of the transistor, which is determined as the physical length of the individual gate fingers included in the field effect transistor (note that the physical length of the gate fingers is often referred to as the “width”) multiplied by the number of gate fingers included in the transistor. Increasing the total gate width of a field effect transistor lower the drain-to-source resistance R_{ds} thereof, and the lower resistance reduces the insertion loss of the pre-distortion circuit 30 to the main RF transistor amplifier 20, which is desirable. However, at very high frequencies, it becomes difficult to impedance match a large field effect transistor 40 to the RF signal source 10 and/or to the main RF transistor amplifier circuit 20 due to the parasitic capacitances C_{gs}, C_{gd} and C_{ds} of field effect transistor 40, as these parasitic capacitances are dependent on the size of field effect transistor 40. To obtain sufficient impedance matching, the size of field effect transistor 40 may be reduced, but this increases the drain-to-source resistance R_{ds} and hence increase the insertion loss of the pre-distortion circuit 30. Thus, at high frequencies (e.g., frequencies of about 30 GHz or more) it may not be possible to obtain both good impedance matching (so that the main RF transistor amplifier 20 operates over a sufficient bandwidth) and sufficiently low insertion loss. Implementing the pre-distortion circuit 30 using a gallium arsenide (“GaAs”) or gallium nitride (“GaN”) based HEMT 40 may allow for higher frequency operation because GaAs and GaN based HEMTs tend to have low parasitic reactances. However, even when using these material systems and implementing the transistor 40 to have the smallest possible size, it may be difficult to design analog pre-distortion circuits that can be used in systems having operational frequency ranges above 50 GHz.

Another issue with the conventional RF transistor amplifier system 1 of FIG. 1A is that the drain-to-source resistance (“Ras”) of field effect transistor 40 is coupled in series along the conductive path connecting the RF signal source 10 to the gate of the main RF transistor amplifier 20. As the size of the field effect transistor 40 is reduced (which, as discussed above, is necessary to achieve high frequency operation), the drain-to-source resistance R_{ds} of field effect transistor 40 increases. Since the power loss of an RF signal passing along a transmission path is calculated as I²R, where I is the amount of current and R is the resistance of the transmission path, the increased drain-to-source resistance R_{ds} results in increased transmission losses (i.e., higher insertion losses). This increase in insertion loss may also make it impractical to use the pre-distortion circuit 30 of FIG. 1A in RF transistor amplifier systems that are designed to operate at frequencies over 50 GHz.

Pursuant to embodiments of the present invention, RF transistor amplifier systems are provided that include distributed analog pre-distortion circuits. The RF transistor amplifier systems disclosed herein may be implemented as MMIC devices, although embodiments of the present invention are not limited thereto. The distributed configuration of the pre-distortion circuit may be used to create an artificial transmission line that may be designed, for example, to have a 50Ω characteristic impedance in order to match the impedance of a connection to the RF signal source, thereby reducing or minimizing return loss. Moreover, the 50Ω impedance matching may be obtained for any number of stages in the pre-distortion circuit because the artificial transmission line topology can be designed to inherently provide a 50Ω characteristic impedance. The number of stages in the distributed analog pre-distortion circuits according to embodiments of the present invention may therefore be selected to provide a desired amount of compensating gain and phase range to compensate for the non-linearities in the main RF transistor amplifier. Thus, the RF transistor amplifier systems according to embodiments of the present invention may be used in systems having much higher operating frequency ranges while providing significant improvements in device linearity. Using the techniques disclosed herein, RF transistor amplifier systems may be implemented in either gallium arsenide or gallium nitride based material systems that include analog pre-distortion circuits and support operation at frequencies up to 300 GHz.

Pursuant to some embodiments of the present invention, RF transistor amplifier systems are provided that comprise an RF transistor amplifier and an artificial transmission line that acts as a distributed pre-distortion circuit. The artificial transmission line comprises a conductive path that is coupled between an RF signal source and the RF transistor amplifier and a plurality of transistors coupled between the conductive path and a reference voltage, with the drain of each transistor is coupled to the conductive path and the source of each transistor is coupled to the reference voltage. A plurality of inductances are provided in series along the conductive path so that the drain of each transistor may be connected in between a respective pair of the inductances. The gate of each transistor may be commonly coupled to a direct current voltage source and to the reference voltage. The drain-to-source capacitances of the transistors form the shunt capacitances of the artificial transmission line.

Pursuant to further embodiments of the present invention, RF transistor amplifier systems are provided that comprise an RF signal source, that is coupled to an RF transistor amplifier by an impedance matching network that comprises a plurality of inductances connected in series along a conductive path. The conductive path (with the inductances formed therealong) connects the RF signal source to the RF transistor amplifier. The impedance matching network also includes a plurality of field effect transistors (e.g., HEMTs) that are shunt coupled to the conductive path. Values of the inductances and values of a drain-to-source capacitances of the field effect transistors are selected so that an impedance at an input of the impedance matching network matches an impedance of the RF signal source. A number of transistors included in the plurality of field effect transistors may be selected to provide a pre-determined amount of pre-distortion.

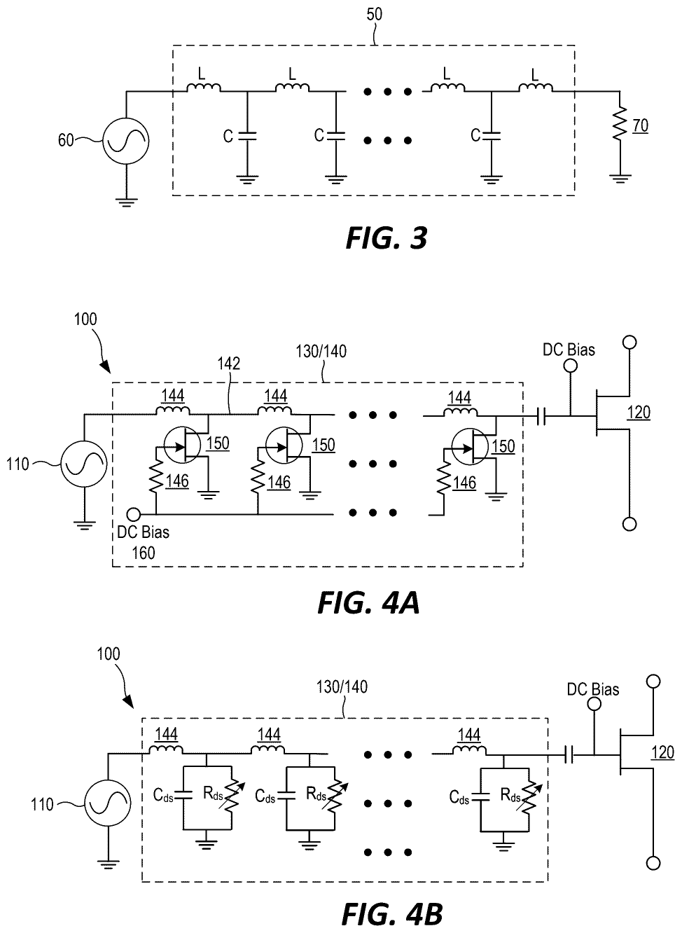

Embodiments of the present invention will now be discussed in greater detail with reference to FIGS. 3-4B.

As discussed above, the RF transistor amplifier systems according to embodiments of the present invention may include pre-distortion circuits that have an artificial transmission line implementation. FIG. 3 is a circuit diagram of a conventional artificial transmission line 50 that is coupled between a signal source 60 and a load 70. As shown in FIG. 3, the artificial transmission line 50 comprises a series of series inductances L and shunt capacitances C. The characteristic impedance of the artificial transmission line of FIG. 3 can be determined as:

$$\sqrt{L / C} = 50 Ω$$

Thus, by selecting the values of inductances L and the capacitances C, the artificial transmission line 50 may be designed to have any appropriate impedance.

An artificial transmission line exhibits low-pass filter behavior. The cut-off frequency f_{cutoff} of the low-pass filter can be determined as:

$${f}_{cutoff} \approx \frac{1}{π \sqrt{L / C}} \cdot \frac{1}{\sqrt{n}}$$

where “n” is the number of stages in the artificial transmission line. Thus, fewer stages in the artificial transmission line allows for a higher cut-off frequency, and hence higher frequency operation. On the other hand, using smaller field effect transistors in each stage reduces the magnitude of the shunt parasitic capacitances, and hence the number of stages can be increased if the size of the field effect transistor in each stage is reduced

Thus, there are at least two ways to design an artificial transmission line that is suitable for high frequency operation. In the first approach, the artificial transmission line has fewer stages, but can have larger shunt capacitances in each stage. In the second approach, the artificial transmission line can have a larger number of stages, but has smaller shunt capacitances in each stage.

FIG. 4A is a circuit diagram of an RF transistor amplifier system 100 according to certain embodiments of the present invention. As shown in FIG. 4A, the RF transistor amplifier system 100 includes an RF signal source 110, a main amplifier circuit 120, and an analog pre-distortion circuit 130. The main amplifier circuit 120 may be any conventional amplifier circuit that includes one or more RF transistor amplifiers. The main amplifier circuit 120 may, for example, include a single RF transistor amplifier or may include two or more RF transistor amplifiers that are coupled, for example, in series (e.g., a multi-stage amplifier) and/or in parallel (e.g., a Doherty amplifier).

As shown in FIG. 4A, the distributed pre-distortion circuit 130 is implemented as an artificial transmission line 140 that includes a plurality of inductances 144 that are implemented along a conductive path 142, as well as a plurality of transistors 150 that are coupled between the conductive path 142 and a reference voltage such as ground. The transistors 150 may be field effect transistors (e.g., HEMT transistors) that exhibit a non-linear drain-to-source resistance R_{ds} as a function of an applied gate-to-source bias voltage. As shown in FIG. 4A, the drain of each field effect transistor 150 may be coupled to the conductive path 142, and the source of each field effect transistor 150 may be coupled to the reference voltage. The gate of each field effect transistor 150 may be coupled to a DC bias voltage source 160 that applies a DC bias voltage to the gates of the transistors 150 that is at least equal to the threshold voltage of the transistors 150. A resistor 146 is coupled in between the gate of each transistor 150 and the DC bias voltage source 160.

As shown in FIG. 4A, driving RF signals output by the RF signal source 110 are provided to the source terminal of each field effect transistor 150. At each field effect transistor 150, the gate-to-drain capacitance (C_{gd}) works as an RF coupling element. Therefore, a part of each driving RF signal at each field effect transistor 150 modulates the gate-to-source voltage thereof. This driving signal (V_{rf}) is superimposed on the DC gate biasing voltage (V_{gs}+V_{rf}). Therefore, the superimposed voltage (V_{gs}+V_{rf}) changes the behavior of the non-linear elements such as R_{ds} (V_{ds}+V_{RF}), C_{gs} (V_{gs}+V_{RF}) and C_{gd} (V_{gd}). Thus, the elements that have values that change in response to the driving RF signal are used to form a desired pre-distortion circuit response.

Field effect transistors have a parasitic drain-to-source capacitance (“C_{ds}”) that arises due to unintended coupling between the drain and source regions and/or terminals of the transistor. Since the transistors 150 of artificial transmission line 140 are coupled between the conductive path 142 and a reference voltage, each transistor 150 inherently acts as a shunt capacitor C_{ds}. In addition, as discussed above, each transistor 150 will also exhibit a non-linear drain-to-source resistance R_{ds} that is a function of an applied gate-to-source bias voltage. Thus, as shown in FIG. 4B, the equivalent circuit of the RF transistor amplifier system 100 of FIG. 4A comprises a conductive path 142 that connects the RF signal source 110 and the main RF transistor amplifier 120. A plurality of inductors 144 are connected in series along the conductive path 142. The drain of each transistor 150 is coupled in between a respective pair of adjacent inductances 144, and the source of each transistor 150 is coupled to the reference voltage. In other words, the transistors 150 are in a common source configuration. Each transistor 150 may be modeled as a parallel capacitor-resistor (“RC”) circuit that is coupled between the conductive path 152 and the reference voltage, where the capacitor C is the intrinsic drain-to-source capacitance C_{ds} of the transistor 150 and the resistor R is the intrinsic nonlinear drain-to-source resistances R_{ds} of the transistor 150. Thus, the pre-distortion circuit 130 may be viewed as a cascade of series L, shunt C, series L circuits that is designed to achieve a desired characteristic impedance value (e.g., 50Ω) that further includes a plurality of shunt non-linear resistances R_{ds}.

Since the pre-distortion circuit 130 is formed as an artificial transmission line 140, it may readily be designed to achieve a desired impedance, such as an impedance of 50Ω. The values of the inductances 144 and the capacitances C_{ds} may be selected to ensure that the artificial transmission line 140 has a cut-off frequency that is above the operating frequency range of the main amplifier 120, with smaller inductance 144 and capacitance C_{ds} values acting to increase the cut-off frequency. The number of transistors 150 included in the distributed pre-distortion circuit 130 may be varied to achieve a desired amount of compensating amplitude and phase based on the linearity characteristics of the main RF transistor amplifier. The drain-to-source resistances R_{ds} of the transistors 150 act as the pre-distortion elements as the drain-to-source resistance R_{ds} varies non-linearly with the gate-to-source bias voltage. In other words, the gate-to-source bias voltage that is applied to the transistors 150 can be varied as a function of the power level of the RF signal output by the RF signal source 110 to provide a desired amount of pre-distortion.

As described above, an artificial transmission line that is suitable for high frequency operation can be provided by forming the artificial transmission line to have fewer stages, with larger shunt capacitances in each stage or, alternatively, by forming the artificial transmission line to have a larger number of stages, but with a smaller shunt capacitance in each stage. As is also described above, the pre-distortion circuit 130 needs to have a relatively low insertion loss. Using larger field effect transistors 150 to implement the artificial transmission line 140 helps lower the insertion loss, but also degrades the impedance match. Thus, a designer may make tradeoffs in selecting the number of stages in the artificial transmission line, the size of the individual field effect transistors 150 included in the artificial transmission line 140, a highest operation frequency and a bandwidth of the operating frequency band to design a pre-distortion circuit 130 that meets the operating frequency band requirements while providing an acceptable insertion loss.

By using a distributed pre-distortion network that is configured to form an artificial transmission line it is possible to impedance match the RF transistor amplifier 120 to the RF signal source 110 over a wide bandwidth since the shunt source-to-drain capacitances C_{ds} of the transistors 150 in combination with the high impedance signal line 142 (with the high impedance provided by the inductors 144) resembles a lumped-element version of a 50Ω (or other desired impedance) transmission line. Distributed amplifiers such as travelling wave amplifiers are known in the art, and have been used as the main amplifier of an RF amplifier system. However, conventional distributed amplifiers tend to not be efficient as the load seen by each transistor is not even close to optimum. Most RF transistor amplifier applications require high efficiency levels. Pursuant to embodiments of the present invention, a distributed amplifier may be used as a pre-distortion circuit, leveraging the non-linear response of the source-to-drain resistances R_{ds} of the transistors 150. Since the pre-distortion circuit operates on the non-amplified RF signal, the lower efficiency is not a concern, and the distributed architecture allows matching the main RF amplifier 120 to the RF signal source 110 over very large bandwidths.

If the pre-distortion circuit 130 only included a single stage (i.e., if the pre-distortion circuit 130 included a single shunt transistor 150 in common source configuration coupled in between a pair of inductances 144 on the conductive path 142), it would be necessary to use a relatively large transistor 150 to obtain a desired amount of pre-distortion (i.e., a desired amount of compensating amplitude and phase). The drain-to-source capacitance C_{ds} of a field effect transistor increases with increasing transistor size, and therefore a single stage pre-distortion circuit would tend to have a poor frequency response since the large transistor would exhibit a large shunt capacitance. In contrast, if a multi-stage pre-distortion network is used that has n transistor stages, then the size of each transistor may be 1/n as compared to the single stage pre-distortion network. The smaller drain-to-source capacitance values C_{ds} exhibited by the smaller transistors allows the cut-off frequency of the artificial transmission line to be set to a desired characteristic impedance value. Moreover, with proper selection of the values of the drain-to-source capacitance and the series inductances it is possible to impedance match the pre-distortion circuit to the RF signal source.

In some embodiments, all of the transistors 150 may have identical designs, and hence each shunt capacitance C_{ds} of the artificial transmission line 140 may have the same value. Likewise, the inductances 144 may each have the same value, and each resistor 146 may also have the same value. It will be appreciated, however, that in other embodiments the capacitance C_{ds}, the inductances 144 and/or the resistor values 146 may be varied between different stages of the artificial transmission line 140.

Embodiments of the present inventive concepts have been described above with reference to the accompanying drawings, in which embodiments of the invention are shown. This inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the terms “comprises” “comprising,” “includes” and/or “including” specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

In the drawings and specification, there have been disclosed typical embodiments of the invention and, although specific terms are employed, they are used in a generic and descriptive sense only and not for purposes of limitation, the scope of the invention being set forth in the following claims.

1. A radio frequency (“RF”) transistor amplifier system, comprising:
an RF transistor amplifier; and
a pre-distortion circuit that comprises a plurality of transistors, wherein each of the transistors is coupled between a conductive path and a reference voltage.

2. The RF transistor amplifier system of claim 1, wherein the transistors are part of an artificial transmission line that is coupled between an RF signal source and the RF transistor amplifier.

3. The RF transistor amplifier system of claim 2, wherein an impedance of the artificial transmission line is set to match an impedance of the RF signal source.

4. The RF transistor amplifier system of claim 1, wherein each of the transistors is a high electron mobility transistor, and wherein a drain of each of the transistors is coupled to the conductive path and a source of each of the transistors is coupled to the reference voltage.

5. The RF transistor amplifier system of claim 4, wherein a plurality of inductances are provided along the conductive path, and the drain of each of the transistors is coupled to the conductive path between a respective pair of the inductances.

6. (canceled)

7. The RF transistor amplifier system of claim 1, wherein the pre-distortion circuit further comprises a plurality of resistors, where each resistor is coupled between the bias voltage source and the gate of a respective one of the transistors.

8. (canceled)

9. The RF transistor amplifier system of claim 1, wherein drain-to-source resistances of the transistors are used to pre-distort RF signals received from the RF signal source.

10. (canceled)

11. A radio frequency (“RF”) transistor amplifier system, comprising:
an RF signal source;
an RF transistor amplifier; and
an artificial transmission line coupled between the RF signal source and the RF transistor amplifier.

12. The RF transistor amplifier system of claim 11, wherein the artificial transmission line comprises a conductive path that connects the RF signal source to the RF transistor amplifier and a plurality of transistors that are coupled between the conductive path and a reference voltage.

13. (canceled)

14. The RF transistor amplifier system of claim 12, wherein a drain of each of the plurality of transistors is coupled to the conductive path and a source of each of the transistors is coupled to the reference voltage.

15. The RF transistor amplifier system of claim 14, wherein a plurality of inductances are provided along the conductive path, and the drain of each of the transistors is coupled to the conductive path between a respective pair of the inductances.

16. The RF transistor amplifier system of claim 14, wherein gates of each of the plurality of transistors are commonly coupled to a voltage source.

17. The RF transistor amplifier system of claim 15, wherein values of each of the inductances are within 20% of each other.

18-19. (canceled)

20. The RF transistor amplifier system of claim 12, wherein the artificial transmission line acts as a pre-distortion circuit that is configured to improve a linearity of the RF transistor amplifier.

21. (canceled)

22. The RF transistor amplifier system of claim 11, wherein each of the transistors is a high electron mobility transistor.

23. A radio frequency (“RF”) transistor amplifier system, comprising:
an RF signal source;
an RF transistor amplifier; and
an impedance matching network that comprises a plurality of inductances connected in series along a conductive path and a plurality of transistors that are shunt coupled to the conductive path,
wherein values of the inductances and values of a drain-to-source capacitance of the field effect transistors are selected so that an impedance at an input of the impedance matching network matches an impedance of the RF signal source.

24. The RF transistor amplifier system of claim 23, wherein the impedance matching network further includes a plurality of inductances that are provided along the conductive path.

25. The RF transistor amplifier system of claim 24, wherein a drain of each of the transistors is coupled to the conductive path between a respective pair of the inductances, and a source of each transistor is coupled to ground.

26. (canceled)

27. The RF transistor amplifier system of claim 23, wherein drain-to-source resistances of the transistors are used to pre-distort RF signals received from the RF signal source.

28. The RF transistor amplifier system of claim 23, wherein a number of transistors included in the pre-distortion circuit is selected to provide a pre-determined amount of pre-distortion.
